(19) United States
(12) Patent Application Publication
(10) Pub. No.: US 2014/0078651 A1
(43) Pub. Date: Mar. 20, 2014

(54) HOUSING, METHOD FOR MANUFACTURING THE SAME AND ELECTORNIC DEVICE USING THE HOUSING

(71) Applicants: SHENZHEN FUTAIHONG PRECISION INDUSTRY CO., LTD., SHENZHEN (CN); FIH (HONG KONG) LIMITED, KOWLOON (HK)

(72) Inventors: SHU-XIANG ZHOU, Shenzhen (CN); HE-XIAN LIN, Shenzhen (CN)

(73) Assignees: FIH (HONG KONG) LIMITED, KOWLOON (HK); SHENZHEN FUTAIHONG PRECISION INDUSTRY CO., LTD., SHENZHEN (CN)

(21) Appl. No.: 13/721,703

(22) Filed: Dec. 20, 2012

(30) Foreign Application Priority Data
Sep. 17, 2012 (CN) 2012103433299

(51) Int. Cl. H05K 5/06; H05K 13/00

(52) U.S. Cl. CPC H05K 5/065; H05K 13/0046; B82B 1/005
USPC 361/679.01; 264/259; 427/401; 312/400; 977/832

(57) ABSTRACT

A housing includes a base body and a waterproof portion formed on the base body. The base body includes an inner wall, and a first end wall adjacent to the inner wall. The waterproof portion is formed on the inner wall and the first end wall. The waterproof portion contains water-absorbent acrylic resin. A method for manufacturing the housing, and an electronic device using the housing are also provided.

### BACKGROUND

1. Technical Field

The present disclosure generally relates to a housing, a method for manufacturing the housing, and an electronic device using the housing.

2. Description of Related Art

A waterproof housing is provided for conventional electronic devices by positioning waterproof gaskets at the gaps of the electronic devices housing. The waterproof gaskets prevent moisture from contacting the electronic components within the electronic device to cause short-circuit or even damage the electronic device. However, under a large water pressure, moisture is still likely to seep into the waterproof housing, causing damage to the electronic device. Consequently, the conventional waterproof housing fails to make electronic devices completely and effectively waterproof.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing, method for manufacturing the housing, and electronic device using the housing. Moreover, in the drawings, like reference numerals designate corresponding parts throughout the several views. Wherever possible, the same reference numbers are used throughout the drawings to refer to the same or like elements of an embodiment.

FIG. 1 is a cross-sectional view of a first embodiment of a housing.

FIG. 2 is a cross-sectional view of a second embodiment of a housing.

FIG. 3 is an exploded view of the first embodiment of an electronic device.

FIG. 4 is an assembled view of the electronic device of FIG. 3.

FIG. 5 is an exploded view of a second embodiment of an electronic device.

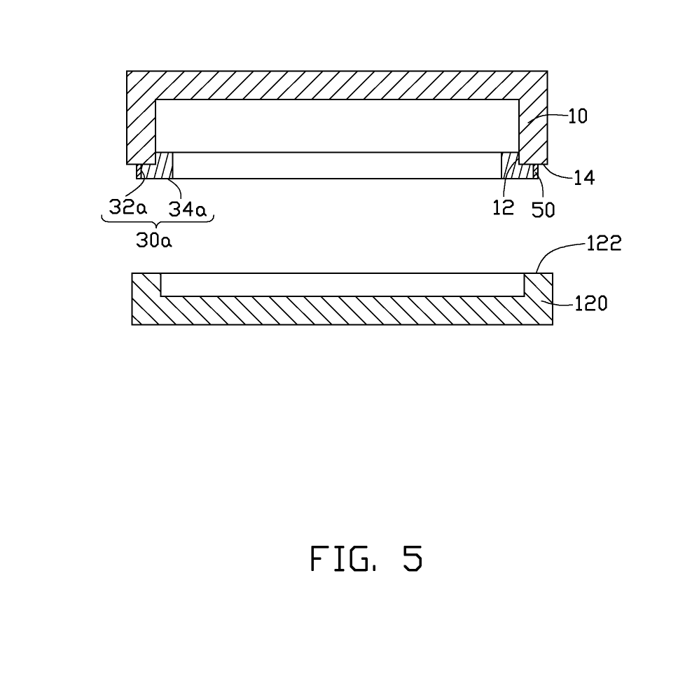

FIG. 6 is an assembled view of the electronic device of FIG. 4.

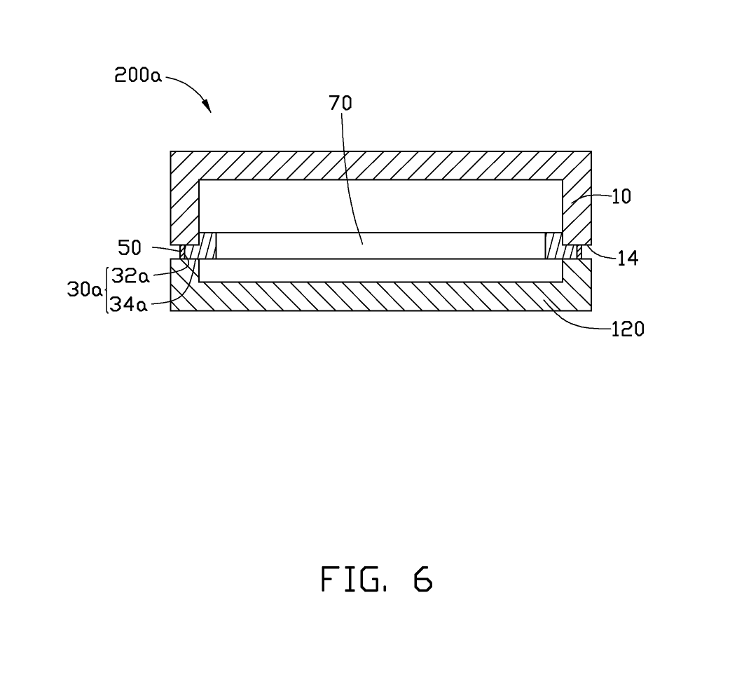

### DETAILED DESCRIPTION

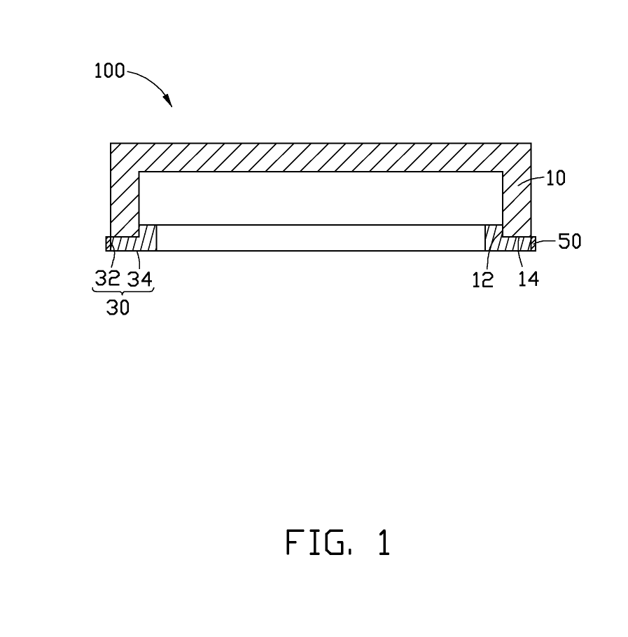

FIG. 1 shows a first exemplary embodiment of a housing 100. The housing 100 includes a base body 10, a waterproof portion 30 formed on the base body 10, and a hydrophobic layer 50 formed on the waterproof portion 30. The base body 10 includes an inner wall 12, and a first end wall 14 adjacent to the inner wall 12. The waterproof portion 30 is formed on the inner wall 12 and the first end wall 14. The waterproof portion 30 includes a first surface 32 and a second surface 34 adjacent to the first surface 32. The first end wall 14 abuts against a surface of the waterproof portion 30 which opposites to the second surface 34. The hydrophobic layer 50 is formed on the first surface 32.

The base body 10 can be made by insert molding. The base body 10 can be made of thermoplastic resin material or thermosetting resin material. The thermoplastic resin material is selected from a group consisting of polyethylene (PE), polyvinyl chloride (PVC), polypropylene (PP), polystyrene (PS), acrylonitrile-butadiene-styrene plastics (ABS), nylon, polycarbonate (PC), polyamide (PA), polyacetal (POM), thermoplastic polyurethane elastomer (TPU), polyphenyl ether, polysulfone (PSF), and polytetrafluroethylene (PTFE). The thermosetting resin material is selected from a group consisting of epoxy resin, phenolic resin (PF), thermosetting polyurethane and silicone resin.

The waterproof portion 30 can be made of thermoplastic resin material. In the embodiment, the waterproof portion 30 is made of thermoplastic resin material containing coupling agent modified nano calcium carbonate, water-absorbent acrylic resin and TPU. In the thermoplastic resin, the mass percentage of the coupling agent modified nano calcium carbonate is about 2% to about 3%, the mass percentage of the water-absorbent acrylic resin is about 3% to about 5%, and the mass percentage of the TPU is about 92% to about 95%. The coupling agent modified nano calcium carbonate provides a high compatibility between the water-absorbent acrylic resin and TPU.

The hydrophobic layer 50 mainly contains fluoroalkyl-modified nano silicon dioxide or fluoroalkyl-modified nano calcium carbonate. The hydrophobic layer 50 has a thickness of about 150 nm to about 300 nm.

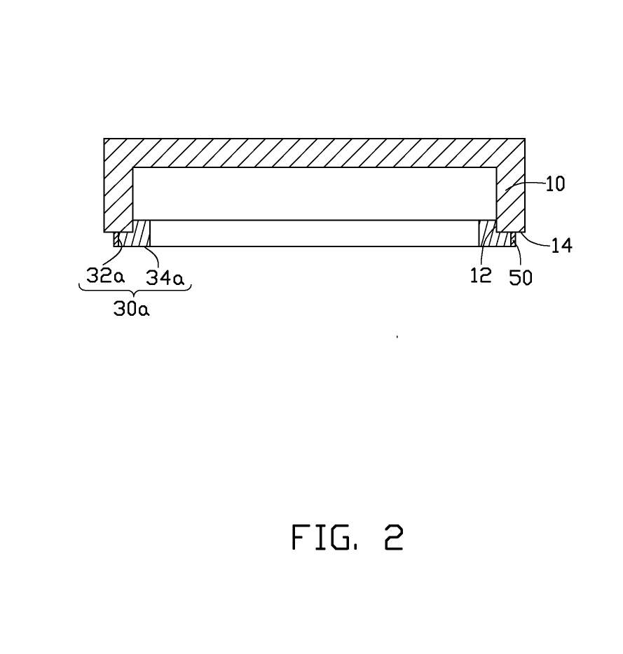

FIG. 2 shows a second exemplary embodiment of a housing 100a. The housing 100a includes a base body 10, a waterproof portion 30a formed on the base body 10, and a hydrophobic layer 50 formed on the waterproof portion 30a. The waterproof portion 30a is formed on the inner wall 12 and covered on partially surface of the end wall 14. The waterproof portion 30a includes a first surface 32a and a second surface 34a adjacent to the first surface 32a. The first end wall 14 abuts against a surface of the waterproof portion 30a which opposites to the second surface 34. The hydrophobic layer 50 is formed on the first surface 32a.

A method for manufacturing the housing 100 may at least includes the following steps:

A base body 10 is provided.

Coupling agent is dispersed in an organic solvent and left standing for about 20 min to about 30 min, and then nano calcium carbonate is added in the mixture. The mixture is stirred at a speed about 700 revolutions per minute (r/min) to about 2000 r/min, followed by a filtering process to separate out the coupling agent modified nano calcium carbonate.

The ratio of the nano calcium carbonate, the coupling agent, and organic solvent is about 3 gram (g) to about 5 g of the nano silicon dioxide, about 1 g to about 3 g of the coupling agent, and the organic solvent may have a volume of about 97 ml to about 99 ml. The coupling agent modified nano calcium carbonate has a particle size in a range of about 20 nm to about 80 nm.

The coupling agent can be titanate coupling agent, silane coupling agent or aluminate coupling agent.

The organic solvent can be at least one selected from the group consist of isopropyl alcohol, ethanol and butanol.

The coupling agent modified nano calcium carbonate, water-absorbent acrylic resin and TPU are mixed uniformly to make a mixture resin material. In the mixture resin, the mass percentage of the coupling agent modified nano calcium carbonate is about 2% to about 3%, the mass percentage of the water-absorbent acrylic resin is about 3% to about 5%, the mass percentage of the TPU is about 92% to about 95%. The water-absorbent acrylic resin has a particle size in a range of about 5 μm to about 10 μm.

The waterproof portion 30 is formed on the base body 10 by insert molding using the mixture resin material. The waterproof portion 30 is formed on the inner wall 12 and the first end wall 14.

Spherically shaped nano silicon dioxides are ultrasonically dispersed in an organic solvent, and then thirteen fluorine octyltriethoxysilane (hearinafter “TFOT”) is added to make a mixture. The mixture is stirred for about 3 hours to about 5 hours, followed by a filtering process to separate out a fluoroalkyl-modified nano silicon dioxide. The fluoroalkyl-modified nano silicon dioxide has a low surface energy.

The ratio of the nano silicon dioxide, the organic solvent, and the TFOT is about 2 g to about 3 g of the nano silicon dioxide, the organic solvent may have a volume of about 30 ml to about 45 ml, and the TFOT may have a volume of about 0.1 ml to about 0.15 ml. The nano silicon dioxide has a particle size in a range of about 50 nm to about 120 nm.

The organic solvent can be, for example, isopropyl alcohol or ethanol, but not limited to the two substances. The organic solution acts as a diluent.

The fluoroalkyl-modified nano silicon dioxide, an organic solvent, and a filmogen are mixed uniformly to make a coating solution. The ratio of the fluoroalkyl-modified nano silicon dioxide, the organic solvent, and the filmogen is about 2 g to about 3 g of the fluoroalkyl-modified nano silicon dioxide, the filmogen has a mass of about 0.5 g to about 0.75 g, and the organic solvent has a volume of about 50 ml to about 75 ml.

The filmogen is benzenethionosulfonic acid sodium salt. The organic solvent can be, for example, isopropyl alcohol or ethanol, but not limited to the two substances. The organic solution acts as a diluent.

The coating solution is sprayed on the first surface 32 of the waterproof portion 30 using a spray gun, and then the substrate 11 is dried at an environment temperature of about 80° C. to about 120° C. for about 25 min to about 40 min to form a hydrophobic layer 50 on the first surface 32. The hydrophobic layer 50 has a thickness of about 150 nm to about 300 nm. The hydrophobic layer 50 contains fluoroalkyl-modified silicon dioxide.

Alternatively, fluoroalkyl-modified nano calcium carbonate can be used instead of the fluoroalkyl-modified silicon dioxide by using nano calcium carbonate instead of nano silicon dioxide.

A method for manufacturing the housing 100a is substantially same as the method for manufacturing the housing 100, except that the waterproof portion 30 is formed on the inner wall 12 and covered on partially surface of the first end wall 14.

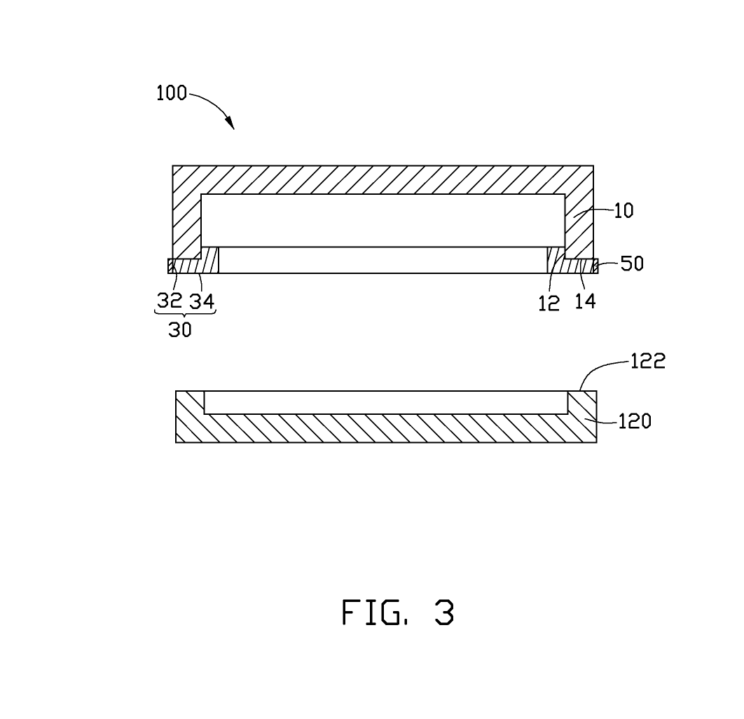

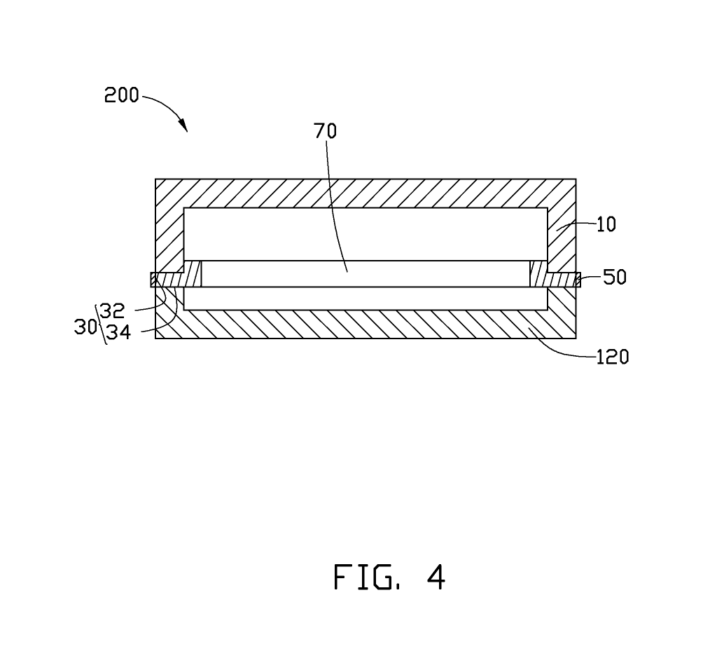

FIGS. 3 and 4 show an electronic device 200 using the housing 100. The electronic device 200 includes a housing 100 and a cover 120 mounted on the housing 120. The cover 120 includes a second end wall 122 abutting against the second surface 31 to form a receiving space 70 between the housing 100 and the cover 120 for receiving electronic components (not shown).

During assembly, the housing 100 is mounted on the cover 120 to make the second surface 34 abutting against the second end wall 122. Then, the waterproof portion 30 having high elastic deformation capacity is pressed towards the housing 100 for reducing a gap defined therebetween, thus avoiding large quantity of water seepage into the receiving space 70 through the gap. Furthermore, the waterproof portion (30, 30a) will absorb the water entering the gap and expand to reduce the gap, which acts to prevent moisture from making contact with electronic components within the electronic device.

FIGS. 3 and 4 show an electronic device 200a using the housing 100a. The electronic device 200a includes a housing 100a and a cover 120. The waterproof portion 30a is formed on the inner wall 12 and covered on partially surface of the end wall 14.

The waterproof portion (30, 30a) located between the housing (100, 100a) and the cover 120 provides an excellent water-resistance to the electrionic device 200a. Additionally, the hydrophobic layer 50 for enhancing the hydrophobic of the first surface 32 make water hardly get past the gap into the receiving space 70, thus further improves the water-resistance of the electrionic device (200, 200a).

It is to be understood, however, that even through numerous characteristics and advantages of the exemplary disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An housing, comprising:
a base body, the base body comprising an inner wall, and a first end wall adjacent to the inner wall; and
a waterproof portion formed on the base body, the waterproof portion being formed on the inner wall and the first end wall, the waterproof portion comprising water-absorbent acrylic resin.

2. The housing of claim 1, wherein the waterproof portion further comprises thermoplastic polyurethane elastomer.

3. The housing of claim 2, wherein the waterproof portion further coupling agent modified nano calcium carbonate.

4. The housing of claim 3, wherein in the waterproof portion, the mass percentage of the coupling agent modified nano calcium carbonate is about 2% to about 3%, the mass percentage of the water-absorbent acrylic resin is about 3% to about 5%, and the mass percentage of the thermoplastic polyurethane elastomer is about 92% to about 95%.

5. The housing of claim 1, further comprising a hydrophobic layer formed on the waterproof portion.

6. The housing of claim 5, wherein the waterproof portion comprises a first surface and a second surface adjacent to the first surface, the first end wall abuts against a surface of the waterproof portion which opposites to the second surface, the hydrophobic layer is formed on the first surface.

7. The housing of claim 6, wherein the hydrophobic layer comprises fluoroalkyl-modified nano silicon dioxide or fluoroalkyl-modified nano calcium carbonate.

8. The housing of claim 7, wherein the hydrophobic layer has a thickness of about 150 nm to about 300 nm.

9. A method for manufacturing the housing, comprising:
providing a base body, the base body comprising an inner wall, and a first end wall interacting with the inner wall;
providing a mixture resin material containing water-absorbent acrylic resin;
forming a waterproof portion on the base body using the mixture resin material by insert molding, the waterproof portion being formed on the inner wall and covered on at least partially surface of the first end wall, the waterproof portion comprising water-absorbent acrylic resin.

10. The method of claim 9, wherein the mixture resin material is formed by mixing coupling agent modified nano calcium carbonate and water-absorbent acrylic resin with thermoplastic polyurethane elastomer.

11. The method of claim 10, wherein the coupling agent modified nano calcium carbonate has a particle size in a range of about 20 nm to about 80 nm.

12. The method of claim 11, wherein the coupling agent modified nano calcium carbonate is manufactured as follows: the coupling agent is dispersed in an organic solvent and left standing for about 20 min to about 30 min, and then nano calcium carbonate is added in the mixture; the mixture is stirred at a speed about 700 r/min to about 2000 r/min and filtered to separate out the coupling agent modified nano calcium carbonate.

13. The method of claim 12, wherein during manufacturing the coupling agent modified nano calcium carbonate, the ratio of the nano calcium carbonat, the coupling agent, and organic solvent is about 3 g to about 5 g of the nano silicon dioxide, about 1 g to about 3 g of the coupling agent, and the organic solvent may have a volume of about 97 ml to about 99 ml.

14. The method of claim 13, further comprising a step of forming a hydrophobic layer on the waterproof portion.

15. The method of claim 15, wherein the hydrophobic layer is formed by spraying using a coating solution containing fluoroalkyl-modified nano silicon dioxide or fluoroalkyl-modified nano calcium carbonate.

16. An electronic device, comprising:
a housing, the housing comprising a base body and a waterproof portion formed on the base body, the base body comprising an inner wall and a first end wall interacting with the inner wall, the waterproof portion being formed on the inner wall and the first end wall, the waterproof portion comprising water-absorbent acrylic resin; and
a cover mounted on the housing, the cover comprising a second end wall abutting against the second surface to form a receiving space between the housing and the cover.

17. The electronic device of claim 16, wherein the waterproof portion further comprises thermoplastic polyurethane elastomer and coupling agent modified nano calcium carbonate.

18. The electronic device of claim 17, wherein in the waterproof portion, the mass percentage of the coupling agent modified nano calcium carbonate is about 2% to about 3%, the mass percentage of the water-absorbent acrylic resin is about 3% to about 5%, and the mass percentage of the thermoplastic polyurethane elastomer is about 92% to about 95%.

19. The electronic device of claim 16, further comprising a hydrophobic layer formed on the waterproof portion.

20. The electronic device of claim 19, wherein the waterproof portion comprises a first surface and a second surface adjacent to the first surface, the first end wall abuts against a surface of the waterproof portion which opposites to the second surface, the hydrophobic layer is formed on the first surface.
